(19) United States
(12) Patent Application Publication
(10) Pub. No.: US 2009/0146179 A1
(43) Pub. Date: Jun. 11, 2009

(54) Planar arrays of photodiodes

(76) Inventors: Young-Kai Chen, Berkeley Heights, NJ (US); Vincent Etienne Houtsma, Berkeley Heights, NJ (US); Andreas Bertold Leven, Gillette, NJ (US); Nils Guenter Weimann, Gillette, NJ (US)

Correspondence Address: Docket Administrator - Room 2F-192;Alcatel-Lucent USA Inc., 600-700 Mountain Avenue, Murray Hill, NJ, 07974, US

(21) Appl. No.: 12/004,597

(22) Filed: Dec. 21, 2007

Related U.S. Application Data
(60) Provisional application No. 61/007,138, filed on Dec. 11, 2007.

(51) Int. Cl. H01L 31/105; H04B 10/04

(52) U.S. Cl. 257/184; 398/183; 257/E31.061

(57) ABSTRACT

An apparatus includes a light detector. The light detector includes a substrate with a planar surface and an array of photodiodes located along the planar surface. Each photodiode has a sequence of different semiconductor layers stacked vertically over the planar surface. The photodiodes are electrically connected in series.

This application claims the benefit of U.S. provisional application No. 60/______, entitled “Planar Arrays of Photodiodes” and filed on Dec. 11, 2007 by Young-Kai Chen, Vincent Etienne Houtsma, Andreas Bertold Leven, and Nils Guenter Weimann, which is incorporated herein in its entirety.

### BACKGROUND

1. Field of the Invention

The invention relates generally to light detectors and more specifically to photodiodes.

2. Discussion of the Related Art

Photo-sensitive diodes are generally referred to as photodiodes. A photodiode can be used as a light detector. When used as a light detector, the sensitivity of the photodiode is approximately proportional to the lateral junction area thereof. For that reason, it is often desirable to have large lateral junction areas in a photodiodes used as light detectors.

### SUMMARY

In one aspect, an apparatus includes a light detector that includes a substrate with a planar surface and an array of photodiodes located along the planar surface. Each photodiode has a sequence of different semiconductor layers stacked vertically over the planar surface. The photodiodes are electrically connected in series.

In some embodiments of the apparatus, the photodiodes are arranged concentrically around a single region of the planar surface.

In some embodiments of the apparatus, each sequence includes a p-i-n vertical stack of semiconductor layers over the planar surface. Also, the p-i-n vertical stacks may be located between the metal connection layers and the substrate.

In some embodiments of the apparatus, each photodiode includes a back-to-back stack of two photodiodes over the planar surface. In such embodiments, each sequence may include an p-i-n vertical stack of semiconductor layers over the planar surface.

In some embodiments, the apparatus further includes an optical modulator connected to transmit a modulated optical carrier to the light detector and an antenna connected to receive an electrical driving signal from the light detector.

In another aspect, a method includes illuminating a planar array of photodiodes with a light beam. The photodiodes of the planar array are electrically connected in series. The method also includes producing an electrical signal from the planar array while the planar array is illuminated by the light beam. The electrical signal is indicative of an intensity of the light beam.

In some embodiments of the method, the illuminating includes passing light of the light beam through a surface of a planar substrate opposite to a surface of the planar substrate on which the planar array is located.

In some embodiments of the method, the illuminating includes illuminating a back-to-back stack of photodiodes located over the planar substrate. The photodiodes of the stack are connected in parallel to a light detection circuit.

In some embodiments, the method further includes optically modulating a data-carrying signal onto an optical carrier, wherein the modulated optical carrier produces the light beam. In such embodiments, the method further includes driving an antenna with the produced electrical signal.

### BRIEF DESCRIPTION OF THE FIGURES

FIG. 1 is top view illustrating a layer of a planar array of photodiodes;

FIG. 2A is a cross-sectional view of a portion one embodiment of the planar array of FIG. 1;

FIG. 2B is cross-sectional view of a portion of an alternate embodiment of the planar array of FIG. 1 in which each of the series-connected photodiode is a pair of back-to-back parallel-connected photodiodes;

FIG. 3 is a block diagram of a wireless transmission system with planar arrays of photodiodes, e.g., one of the planar arrays of FIGS. 1, 2A, and/or 2B;

FIG. 4 is a cross-sectional view of a connector between the planar array of photodiodes and a coaxial cable in the wireless transmission system of FIG. 3;

FIG. 5 is a flowchart illustrating a method for fabricating planar arrays of photodiodes, e.g., planar arrays of photodiodes of FIGS. 1 and 2A;

FIGS. 6-9 are cross-sectional views through portions of intermediate structures fabricated during performance of the method of FIG. 5;

FIG. 10 is a cross-sectional view through a portion of a planar array of photodiodes fabricated by the method of FIG. 5; and

FIG. 11 is a flow chart illustrating a method of operating a planar array of photodiodes, e.g., the planar arrays of FIGS. 1, 2A, 2B, and 10.

In the Figures and text, similar reference numbers refer to features with substantially similar functions and/or substantially similar structures.

In some of the Figures, the relative dimensions of one or more features may be exaggerated to more clearly illustrate the elements therein.

Herein, various embodiments are described more fully by the Figures and the Detailed Description of Illustrative Embodiments. Nevertheless, the inventions may be embodied in various forms and are not limited to the specific embodiments that are described in the Figures and/or the Detailed Description of Illustrative Embodiments.

### DETAILED DESCRIPTION OF ILLUSTRATIVE EMBODIMENTS

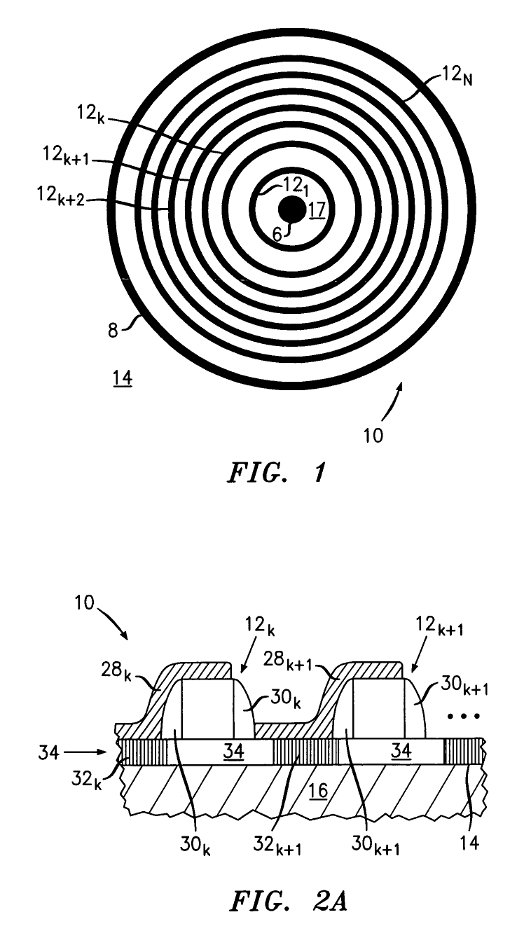

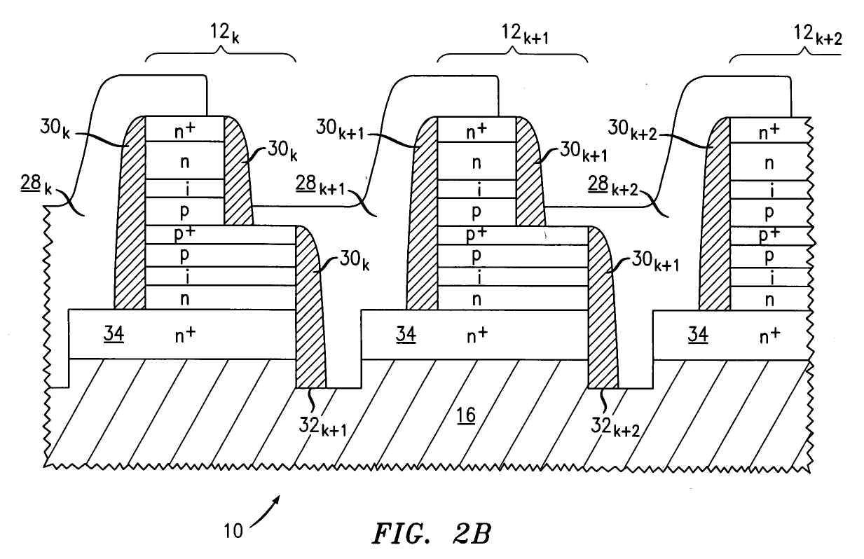

FIGS. 1 and 2A illustrate an exemplary embodiment of a planar array 10 of photodiodes 12₁, . . . , 12ₖ, 12ₖ₊₁, . . . , 12_{N}. The planar array 10 is located along a planar surface 14 of a substrate 16, e.g., a semiconductor or dielectric substrate. In the planar array 10, the individual photodiodes 12₁, . . . , 12_{N} are electrically connected is series between electrodes 6, 8. The electrodes 6, 8 carry a current or a voltage difference indicative of a light intensity incident on the planar array 10 of photodiodes 12₁, . . . , 12_{N}.

In the exemplary planar array 10, the photodiodes 12₁, . . . , 12_{N} are concentric annuli, which are centered about a central region 17 of the substrate 16. The electrode 6 is, e.g., a metal electrode that directly electrically connects to one side of the inner-most photodiode 12₁. The electrode 8 is an annular metal electrode that directly electrically connects to one side of the outer-most photodiode 12_{N}.

The concentric arrangement of the photodiodes 12₁, . . . , 12_{N} in the planar array 10 may improve detection sensitivity when the planar array 10 is used to detect a light beam whose cross section approximately matches the area of the planar array 10. In such embodiments of the planar array 10, it may also be useful to approximately match the radial distribution of areas of the photodiodes 12₁, . . . , 12_{N} to the radial intensity profile of the light beam whose intensity is to be detected or measured.

In other embodiments of a planar array, the photodiodes may have different relative positions and/or may also have different overall relative shapes.

Referring to FIG. 2A, each photodiode 12₁, . . . , 12_{N} in the planar array 10 is a p-i-n diode with the same sequence of semiconductor layers. The semiconductor layers are oriented vertically with respect to the primary planar surface 14 of the substrate 16. An exemplary top-to-bottom sequence is a top heavily doped p+-type semiconductor layer, a p-type semiconductor layer, an intrinsic semiconductor layer, an n-type semiconductor layer, and a bottom heavily doped n+-type semiconductor layer. In the sequence, the p-type semiconductor layer, intrinsic semiconductor layer, and n-type semiconductor layer form the p-i-n photodiode. The top p+-type semiconductor layer and the bottom n+-type semiconductor layer 34 function as electrodes for the p-i-n type photodiodes 12₁, . . . , 12_{N}. In alternate embodiments the order of the sequence of semiconductor layers may have p-type and n-type dopants exchanged.

In the planar array 10, laterally adjacent photodiodes 12₁, . . . , 12_{N} are directly electrically connected in series. In particular, the planar array 10 includes metal connection layers 28ₖ, 28ₖ₊₁, dielectric sidewalls 30ₖ, 30ₖ₊₁, inter-diode isolation regions 32ₖ, 32ₖ₊₁, and top and bottom p+-type and n+-type semiconductor layers to support the series electrical connections. The metal connection layer 28ₖ₊₁ directly electrically connects the top p+-type semiconductor layer of the photodiode 12ₖ₊₁ to the bottom n+-type semiconductor layer 34 of the adjacent photodiode 12ₖ. The dielectric sidewalls 30ₖ, 30ₖ₊₁ electrically insulate other parts of the photodiodes 12ₖ, 12ₖ₊₁ from the metal connection layers 28ₖ, 28ₖ₊₁. The inter-diode isolation regions 32ₖ, 32ₖ₊₁ electrically insulate adjacent portions of bottom n+-type semiconductor layer 34 so that bottoms of the adjacent photodiodes 12ₖ, 12ₖ₊₁ are not electrically shorted together.

FIG. 2B shows an embodiment for a second planar array 10 of photodiodes 12₁, . . . , 12_{N} as shown in FIG. 1. In this planar array 10, each photodiode 12₁, 12_{N} is a pair of p-i-n diodes that are physically stacked back-to-back. In each photodiode of a back-to-back pair, the sequence of semiconductors layers is: an n+-type layer (n+), an n-type layer (n), an intrinsic-type layer (i), a p-type layer (p), and a p+-type layer (p+). The two photodiodes of a back-to-back pair have different n+-type semiconductor layers and share a common p+-type semiconductor layer. Since the two n+-type layers of a back-to-back pair, e.g., of the photodiode 12ₖ₊₁, connect directly to the same metal connection layer, e.g., metal connection layer 28ₖ₊₁, and the p+-type layer of the same back-to-back pair connects via a metal connection layer, e.g., the metal connection layer 28ₖ₊₂, to the next back-to-back pair, e.g., of the photodiode 12ₖ₊₂, the photodiodes of a back-to-back pair are electrically connected in parallel. A In this second planar array 10, laterally adjacent photodiode pairs 12₁, . . . 12_{N} are directly electrically connected in series. In particular, this planar array 10 includes the metal connection layers 28ₖ, 28ₖ₊₁, 28ₖ₊₂, the dielectric sidewalls 30ₖ, 30ₖ₊₁, 30ₖ₊₂, the inter-diode isolation regions 32ₖ₊₁, 32ₖ₊₂, and segments of the bottom n+-type semiconductor layer 34 that support selected inter-diode electrical connections. The metal connection layers, e.g., the layer 28ₖ₊₁, directly connect top and bottom n+-type semiconductor layers of the photodiode 12ₖ₊₁ to intermediate p+-type semiconductor layer of the adjacent photodiode 12ₖ. The dielectric sidewalls 30ₖ, 30 ₖ₊₁, 30ₖ₊₂ electrically insulate other parts of the photodiodes 12ₖ, 12ₖ₊₁, 12ₖ₊₂ from the metal connection layers 28ₖ, 28ₖ₊₁, 28ₖ₊₂. The inter-diode isolation regions 32ₖ, 32ₖ₊₁ insulate adjacent portions of bottom n+-type semiconductor layers 34 so that the adjacent photodiodes 12ₖ, 12ₖ₊₁, 12ₖ₊₂ are not shorted together electrically.

In this second planar array 10, the vertical stacking of p-i-n photodiodes into pairs 12₁, . . . , 12ₖ₊₁ produces a higher effective light sensing area per unit surface area than an array of p-i-n photodiodes with the same lateral diameters, but not being vertically stacked. In particular, the back-to-back stacking results in a vertically stacked pair of semiconductor junctions in each photodiodes 12₁, . . . , 12_{N}. This vertical stacking can substantially increase the effective sensing area for light perpendicularly incident onto the planar array 10 with respect to the sensing area of the planar array 10 of FIG. 2A. Thus, the vertical stacking of photodiodes into back-to-back pairs can improve the sensitivity per-unit surface-area of a planar array of photodiodes.

In the planar arrays 10 of FIGS. 2A and 2B, the substrate 16 may be substantially transparent to the wavelength of light to be detected or measured by the planar array 10. Then, a beam of such light can be passed through a backside of the substrate 16 without being attenuated by the metal connection layers 28ₖ, 28ₖ₊₁. In such an arrangement, the planar array of p-i-n photodiodes may react to the light intensity without a significant portion of the light beam being absorbed outside of the light-sensitive semiconductor junction regions.

In alternate embodiments the order of p-type and n-type semiconductor layers may be interchanged in the planar arrays 10 shown in FIGS. 2A and 2B.

A series-connected planar array of photodiodes, e.g., as shown in FIGS. 1, 2A, and 2B, can be used to make an advantageous, high-speed, light detector.

For example, a planar array of vertically oriented photodiodes provides a larger lateral junction area than the single photodiodes thereof. Since the light sensitivity of a photodiode is proportional to the lateral junction area, replacing a single vertical photodiode with a planar array of such photodiodes typically produces an increased sensitivity to light.

Also, a planar array of electrically “series-connected” photodiodes typically has a lower capacitance than a single large photodiode having a lateral junction area equal to that of the entire planar array provided that photodiodes of planar array have the same junction structure as the single large photodiode. In a series-connected planar array, the total capacitance is also lower, because the total capacitance of such an array is equal to the inverse of the sum of the inverses of the capacitances of the individual photodiodes therein. Even though the total resistance of such a planar array of photodiodes will be larger than the resistance of an individual photodiode therein, making an array of such individual photodiodes does not necessarily negatively impact the operating speed. In particular, the process of series connecting individual photodiodes can be done such that the total resistance scales up at a rate similar to the rate at which the total capacitance scales down. Since the parasitic time constant of a diode is the product of a diode's resistance and its capacitance, the parasitic time constant of such an array can remain fairly constant as more individual photodiodes are serially connected thereto. Indeed, as compared with a single photodiode of the same total lateral junction area and junction structure, such a planar array can have a much shorter minimum response time. Thus, such a planar array may allow the total lateral junction area to be increased without undesired reduction in the maximum operating speed of a photodiode light detector. For these reasons, a planar array of series-connected photodiodes can provide a high-sensitivity light detector that is adapted for high operating speeds.

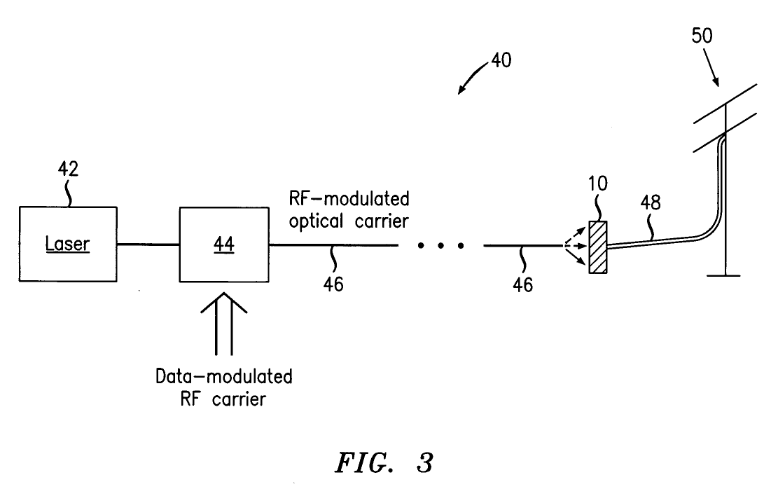

FIG. 3 illustrates an exemplary wireless transmission system 40 that may incorporate any of the planar arrays 10 of FIGS. 1, 2A, 2B as a high-speed light detector. The wireless transmitter 40 includes a laser 42, an optical modulator 44, an optical transmission fiber 46, the planar array 10 of photodiodes 12₁, . . . , 12_{N}, a coaxial cable 48, and a radio-frequency (RF) transmission antenna 50. The optical modulator 44 modulates a data-modulated RF carrier onto the optical carrier from the laser 42 thereby modulating data onto the optical carrier. The optical modulator 44 also transmits the data-modulated optical carrier to the optical transmission fiber 46, which provides a low-loss optical link to the remainder of the wireless transmission system 40. The optical transmission fiber 46 delivers the data-modulated optical carrier to the back-side of the planar array 10 of photodiodes 12₁, . . . , 12_{N}. By electrically detecting the data-modulated optical carrier, the planar array 10 of photodiodes 12₁, . . . , 12_{N} effectively demodulates a data-modulated RF electrical signal from the received data-modulated optical carrier. The planar array 10 of photodiodes 12₁, . . . , 12_{N} outputs the data-modulated RF electrical signal to the coaxial cable 48, which drives the transmission antenna 50 with said data-modulated RF electrical signal.

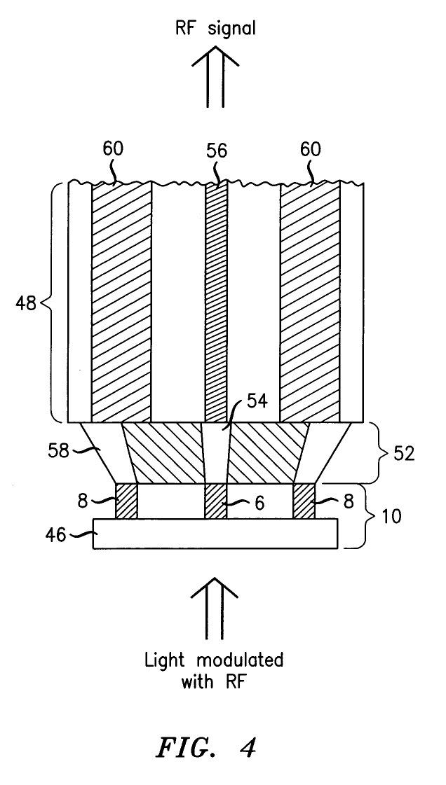

FIG. 4 illustrates an exemplary adapter 52 for electrically connecting the planar array 10 of photodiodes 12₁,. . . , 12_{N} of FIG. 1 to the coaxial cable 48 in the wireless transmission system 40 of FIG. 3. The adapter 52 has a central conductor 54 that physically contacts the central electrode 6 of the planar array 10 and the axial conductor 56 of the coaxial cable 48. The adapter 52 has a tapered annular conductor 58 that physically contacts the annular ground electrode 8 of the planar array 10 and the braided wire jacket 60 of the coaxial cable 48. Thus, the adapter 52 electrically connects the central electrode 6 of the planar array 10 to the axial conductor 56 of the coaxial cable 48 and electrically connects the annular outer electrode 8 of the planar array 10 to the braided wire jacket of the coaxial cable 48. The adapter 52 can compensate for differences between the diameter of the planar array 10 and the diameter of the coaxial cable 48. The adapter 52 may also serve as a heat sink to limit the temperature rise in the diode array 10 in wireless transmission system 40.

In the wireless transmission system 40 of FIG. 3, the intermediate conversion of a data-modulated RF electrical carrier to an RF modulated optical carrier allows the convenient spatially separation of the data modulator 44 from the RF transmission antenna 50. In such a wireless transmission system 40, the planar array 10 provides a light detector that is capable of producing a high power driving signal for the RF transmission antenna 50 at high driving frequencies.

In case of top-illumination of the planar array 10, the top surface of the planar array would be coated with an anti-reflective layer to efficiently couple light from the optical fiber into the planar array. In case of bottom illumination of the planar array 10, the bottom surface of the planar array would be coated with an anti-reflective layer known to a skilled person. In both cases, additional optical elements such as lenses and collimators may be used to enhance the coupling efficiency between optical fiber and planar array 10.

Devices and systems for wireless transmission, which may be easily modified to use the planar array 10 of FIGS. 1-2 for a light detector therein are described, e.g., in U.S. patent application Ser. No. 11/366,145, filed on Mar. 2, 2006 by Young-Kai Chen and Andreas B. Leven and/or U.S. patent application Ser. No. 11/376,491, filed on Mar. 15, 2006 by Douglas M. Gill, Mahmoud Rasras, and Kun-Yii Tu. These patent applications are incorporated herein by reference in their entirety.

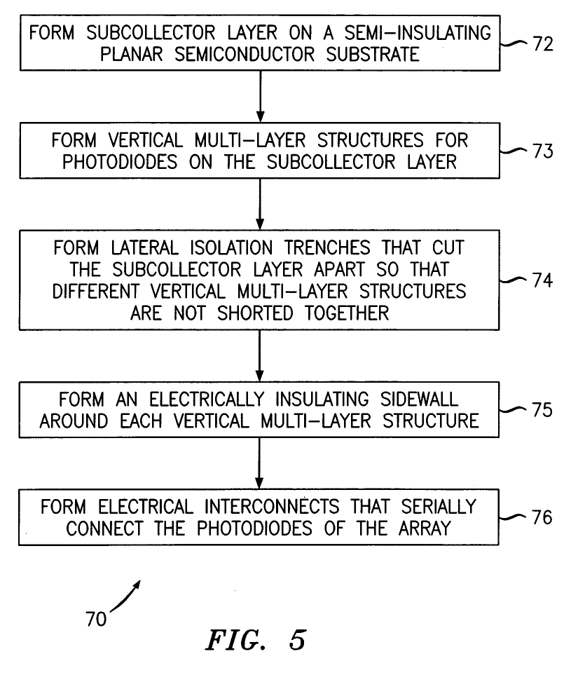

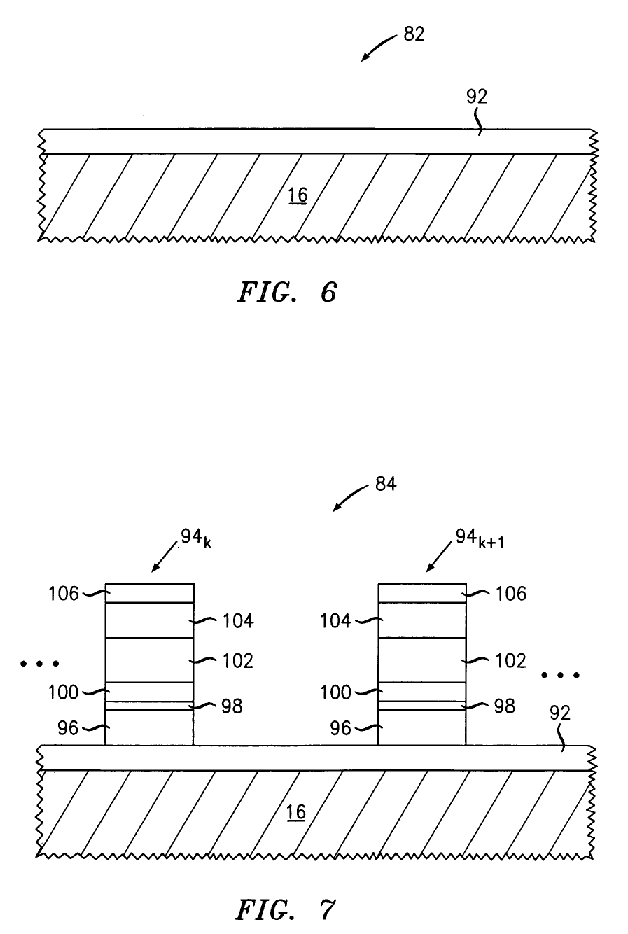

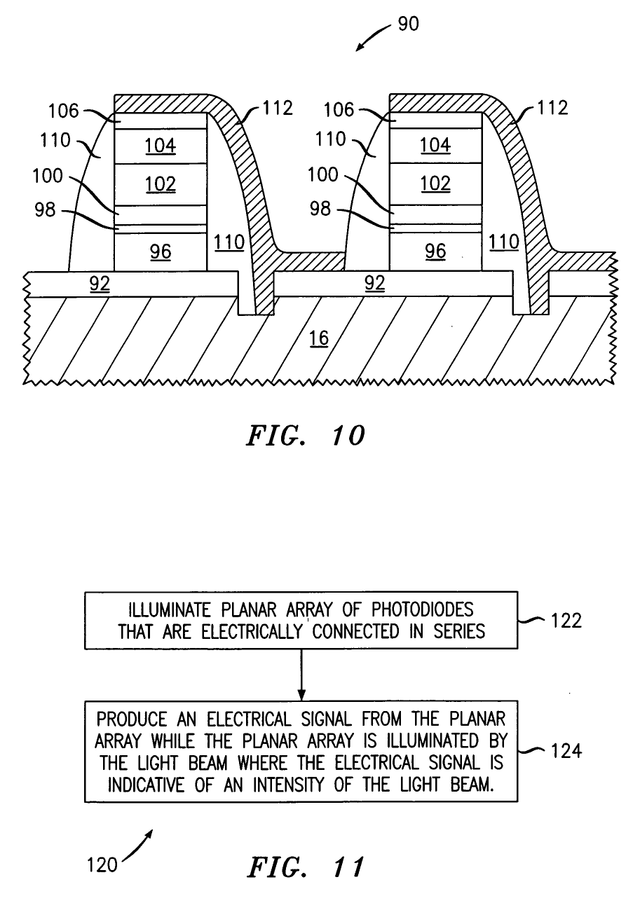

FIG. 5 illustrates a method 70 for fabricating a planar array of photodiodes, e.g., the planar arrays 10 of FIGS. 1 and 2A. The method 40 produces portions of intermediate structures 82, 84, 86, 88, as shown in FIGS. 6-9, and produces the portion of the final structure 90, as shown in FIG. 10.

The method 70 includes forming a subcollector layer 92 on a semi-insulating planar InP substrate 16 as shown in the intermediate structure 82 of FIG. 6 (step 72). The subcollector layer 92 is a heavily n-doped layer that will provide the bottom electrical contacts for the final photodiodes. For example, the subcollector layer may be an n+-type crystalline InP layer having a thickness of about 600 nanometers (nm) and about 5×101¹⁸ n-type dopant atoms per centimeter-cubed (cm³). Exemplary n-type dopants include silicon (Si) and/or sulfur (S). The planar InP substrate 16 provides mechanical support for the structure 92 and the final planar array. For example, the planar InP substrate 16 may be about 30 micrometers (pm) of intrinsic crystalline InP. Thus, the InP substrate 16 may have, e.g., about 10¹⁵ or less dopant atoms per cm³.

The method 70 includes forming a lateral distribution of vertical multi-layer structures 94ₖ, 94ₖ₊₁ for the individual photodiodes on the crystalline InP subcollector layer 92 as shown in the intermediate structure 84 of FIG. 7 (step 73). For example, the lateral distribution may be a concentric arrangement of annular multi-layer structures 94ₖ, 94ₖ₊₁ as in the planar array 10 of photodiodes 12₁, . . . , 12_{N} shown in FIG. 1. The vertical multi-layer structures 94ₖ, 94ₖ₊₁ are fabricated by a series of conventional deposition and doping steps, which are followed by a conventional mask-controlled wet or dry etch to pattern the vertical multi-layer structures 94ₖ, 94ₖ₊₁ from the deposited semiconductor layers.

The series of conventional deposition and doping steps produces the layer structure of the vertical multi-layer structures 94ₖ, 94ₖ₊₁. An exemplary bottom-to-top layer structure for the multi-layer structures 94ₖ, 94ₖ₊₁ is as follows. The bottom layer 96 is about 200 nm of crystalline n-type InP with about 5×10¹⁶ n-type dopant atoms per cm³, e.g., Si or S atoms. The next higher layer 98 is a thin barrier layer of about 5 nm of crystalline n-type InP. In the thin barrier layer 98, the n-type dopant atom concentration is about 5×10¹⁷ per cm³. The next higher layer 100 is about 50 nm of (In₁₋ₓGaₓ)(As_{1-y}P_{y}) semiconductor, which has an alloy composition that is bottom-to-top graded. The grading is such that x varies linearly in a bottom-to-top direction from about 0.18 to about 0.47, and y varies linearly in a bottom-to-top direction from about 0.64 to about 0.0. In this layer, the n-type dopant atom concentration varies linearly from a bottom value of about 5×10¹⁶ (i.e., n-type) to a top value of about 10¹⁵ (i.e., intrinsic-type). The next higher layer 102 is configured to absorb light at about a telecommunications wavelength, i.e., about 1.55 μm. This layer 102 has about 500 nm of crystalline p-type (In_{0.53}Ga_{0.47})As. In the layer 102, p-type dopant atoms (e.g., zinc (Zn) and/or beryllium (Be) atoms) have a concentration that is graded from a bottom value of about 5×10⁷ per cm³ to a top value of about 2×10¹⁸ per cm³. The layer 102 typically has a bandgap that is smaller than the bandgap of parts of the graded layer 100. In another embodiment, this layer may consist of (Ga_{0.5}As_{0.5})Sb, enabling a “type-II” band alignment with the InP material of layer 98, hence obliterating the need for a graded layer 100. In both cases, the composition of layer 102 may be varied across the layer in addition to the doping concentration to produce an intrinsic electric field in the layer 102, thus accelerating photo-generated electrons toward the collection layer 98.

The next layer 104 is a barrier layer of about 200 nm of crystalline p+-type InP. This layer 104 has about 10¹⁹ p-type dopant atoms per cm³ ((e.g., Zn and/or Be atoms). The top layer 106 is an electrode layer of about 30 nm of p+-type (In_{0.53}Ga_{0.47})As. This layer 106 also has about 10¹⁹ p-type dopant atoms per cm³.

In the above sequence of semiconductor layers, the linear alloy and/or dopant graded layers can also be approximated by stacks of thinner semiconductor layers of fixed alloys and dopant concentrations intermediate to the alloys and dopant concentrations of the final and initial semiconductor layers.

A conventional mask-controlled wet or dry etch patterns the multi-layer thereby producing the lateral relief pattern of the vertical multi-layer structures 94ₖ, 94ₖ₊₁. If a wet etch is employed, an etch chemistry that stops on the crystalline InP subcollector layer 92 or the InP substrate 16 can be selected. In the case of a dry etch, the etch depth may be controlled by timing or by using an in-situ interferometric or plasma-spectroscopic technique.

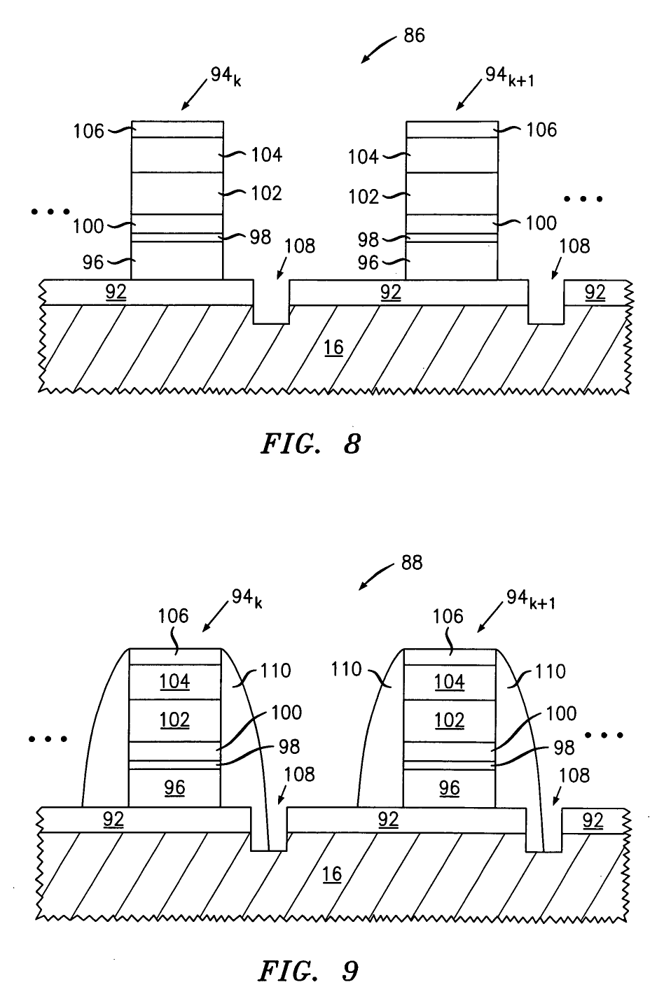

The method 70 involves forming a plurality of lateral isolation trenches 108 that cut through the subcollector layer 92 so that the bottoms of different ones of the vertical multi-layer structures 94ₖ, 94ₖ₊₁ are not shorted together, e.g., as shown in intermediate structure 86 of FIG. 8 (step 74). The lateral isolation regions 108 may be produced by performing a dry or wet etch of the subcollector layer 92 under the control of another lithographically produced mask layer (not shown). The etch chemistry is selected to substantially stop on the semi-conducting InP substrate 16, or a dry etch with in-situ control is selected. Alternately, the lateral isolation regions 108 may be produced via an ion-implantation, e.g., a damaging ion-implantation.

The method 70 involves forming an electrically insulating sidewall 110 around each vertical multi-layer structure 94ₖ, 94ₖ₊₁ thereby producing the intermediate structure 88 of FIG. 9 (step 75). The sidewalls 110 can be formed by doing a conventional blanket deposition of dielectric and then, performing a mask-controlled etch to narrow the widths of the sidewalls 110. The blanket deposition may produce a layer of silicon dioxide, silicon nitride, Benzo-Cyclo-Butene (BCB), or polyimide. The etch is performed so that the sidewalls only overlap the isolation trench 108 on one side of each vertical multi-layer structure 94ₖ, 94ₖ₊₁.

The method 70 involves forming both electrical interconnects 112 that serially connect the photodiodes 94ₖ, 94ₖ₊₁ together and a pair of electrodes (not shown), e.g., the inner and outer metal electrodes 6, 8 of FIG. 1 (step 76). The pair of electrodes directly connect to one side of to the first photodiode of the array and to the other side of the last serially connected photodiode of the array. The interconnects 112 and electrodes may be formed by a conventional metal deposition, e.g., a metal evaporation-deposition, metal electroplating, or a metal sputtering process. The patterned form of the interconnects 112 may be obtained by controlling the deposition(s) with a lithographically produced mask and/or through a liftoff process, and/or through a lithographically controlled etch process applied after blanket metal deposition. Exemplary three-layer metal stacks for the interconnects 112 and/or electrodes include the conventional bottom-to-top compositions: Ti/Pt/Au, Pd/Pt/Au, Pd/W/Au, and Pd/Ru/Au. In these compositions, the bottom metal layer, middle metal layer, and top metal layer may have the respective thickness ranges 1 nm to 10 nm, 10 nm to 50 nm, and 500 nm to 1,000 nm.

One of skill in the art would readily be able to determine how to modify the method 70 in order to fabricate the planar array 10 of FIG. 2B in which photodiodes are vertically stacked in pairs over the substrate 16.

The method 70 involves processing steps that are readily compatible with techniques for fabricating high-speed heterojunction bipolar transistors (HBTs). For example, U.S. Pat. No. 6,911,716 and U.S. patent application Ser. No. 10/624,038, which was filed on Jul. 21, 2003 by Young-Kai Chen et al, may describe some such techniques for fabricating HBTs. This patent and patent application are incorporated herein by reference in their entirety. In light of the above disclosure, one of skill in the art would be able to easily monolithically integrate high-power planar arrays of photodiodes as described herein and high-speed electronics circuitry on the same planar substrate.

FIG. 11 illustrates a method 120 for operating a planar array of photodiodes as a light detector, e.g., the planar arrays 10 of FIGS. 1, 2A, and 2B and the planar array 90 of FIG. 10.

The method 120 includes illuminating the planar array of photodiodes while the photodiodes are electrically connected in series (step 122). Preferably, the illuminating step involves illuminating a backside of a transparent substrate that supports the planar array where the backside is opposite the side of the substrate supporting metallization. Then, the metallization layers can be positioned to not interfere with the detection of the illuminating light beam by the photodiodes. The illuminating step may also involve illuminating a back-to-back stack of photodiodes over the planar substrate, e.g., as shown in FIG. 2B.

The method 120 includes producing an electrical signal from the output electrodes of the planar array while the planar array is illuminated by the light beam (step 124). The voltage or current associated with the produced electrical signal is indicative of an intensity of the light beam being detected by the planar array.

In some embodiments, the method 120 also includes optical modulating a data or analog signal carrying high frequency electrical signal onto an optical carrier, e.g., a modulated RF signal. The produced modulated optical carrier is used to illuminate the planar array of photodiodes at above step 112. In such embodiments, the method 120 may also involve driving an antenna with the electrical signal produced at above step 124. That is, these embodiments provide for operating a wireless transmission system, e.g., the wireless transmission system 40 of FIG. 3.

The invention is intended to include other embodiments that would be obvious to one of skill in the art in light of the description, figures, and claims.

What we claim is:

1. An apparatus, comprising:
light detector including:
a substrate having a planar surface; and
an array of photodiodes located along the planar surface, each photodiode having a sequence of semiconductor layers stacked vertically over the planar surface; and
wherein the photodiodes are serially electrically connected to form a light detector.

2. The apparatus of claim 1, wherein the photodiodes are arranged concentrically around a single region of the planar surface.

3. The apparatus of claim 1, wherein each sequence includes an p-i-n vertical stack of semiconductor layers over the planar surface.

4. The apparatus of claim 3, wherein one of an n-type semiconductor layer and a p-type semiconductor layer of the p-i-n stack has a bandgap that is less than an energy of a photon at a wavelength of 1.55 μm and the other of the n-type semiconductor layer and the p-type semiconductor layer of the p-i-n stack has a bandgap greater than the energy of a photon at a wavelength of 1.55 μm.

5. The apparatus of claim 1, the light detector includes an array of metal connection layers, each metal connection layer serially connecting one of the photodiodes to a physically adjacent photodiode on the planar surface.

6. The apparatus of claim 3, the light detector includes an array of metal connection layers that electrically connect the photodiodes in series.

7. The apparatus of claim 6, wherein the p-i-n stacks are located between the metal connection layers and the substrate.

8. The apparatus of claim 3, wherein the photodiodes are arranged concentrically around a single region of the planar surface.

9. The apparatus of claim 1, wherein each photodiode includes a back-to-back stack of two photodiodes over the planar surface of the substrate.

10. The apparatus of claim 9, wherein the photodiodes of each back-to-back stack are electrically connected in parallel to a remainder of the array.

11. The apparatus of claim 9, wherein the photodiodes are arranged concentrically around a single region of the planar surface.

12. The apparatus of claim 9, wherein each sequence includes a p-i-n vertical stack of semiconductor layers over the planar surface.

13. The apparatus of claim 9, the light detector includes an array of metal connection layers, each metal connection layer serially connecting one of the stacks of two photodiodes to a physically adjacent one of the stacks on the planar surface.

14. The apparatus of claim 1, further comprising:
an optical modulator connected to transmit a modulated optical carrier to the light detector; and
an antenna connected to receive an electrical driving signal from the light detector.

15. The apparatus of claim 14, wherein each photodiode includes a back-to-back stack of two photodiodes, the photodiodes of each back-to-back stack are electrically connected in parallel to a remainder of the planar array.

16. A method comprises:
illuminating a planar array of photodiodes with a light beam, the photodiodes of the planar array being electrically connected in series; and
producing an electrical signal from the planar array while the planar array is illuminated by the light beam, the electrical signal being indicative of an intensity of the light beam.

17. The method of claim 16, wherein the illuminating includes illuminating the planar array by passing light through a surface of a planar substrate opposite to a surface of the planar substrate on which the planar array is located.

18. The method of claim 16, wherein the illuminating includes illuminating a back-to-back stack of photodiodes over the planar substrate, the photodiodes of the stack being connected in parallel to a light detection circuit.

19. The method of claim 14, further comprising:
optically modulating a data-carrying signal onto an optical carrier, the modulated optical carrier producing the light beam; and
driving an antenna with the produced electrical signal.
